(19) United States
(12) Patent Application Publication
(10) Pub. No.: US 2025/0093782 A1
(43) Pub. Date: Mar. 20, 2025

(54) METHOD FOR OPERATING A PROJECTION EXPOSURE SYSTEM, AND PROJECTION EXPOSURE SYSTEM

(71) Applicant: Carl Zeiss SMT GmbH, Oberkochen (DE)

(72) Inventors: Malte LANGENHORST, Aalen (DE); Fabian LETSCHER, Oberkochen (DE); Werner WEISS, Ulm (DE); Hans Michael STIEPAN, Aalen (DE); Andre DIRAUF, Aalen (DE)

(21) Appl. No.: 18/966,572

(22) Filed: Dec. 3, 2024

Related U.S. Application Data
(63) Continuation of application No. PCT/EP2023/062496, filed on May 10, 2023.

(30) Foreign Application Priority Data
Jun. 8, 2022 (DE) 10 2022 205 814.3

(51) Int. Cl. G03F 7/00

(52) U.S. Cl. CPC G03F 7/70258; G03F 7/70233; G03F 7/70316

(57) ABSTRACT

A method of operating a projection exposure apparatus for microlithography, comprises: heating an optical element of the projection exposure apparatus by irradiating a surface of the optical element with heating radiation during a break in operation in which the surface of the optical element is not irradiated by exposure radiation. An inhomogeneous temperature distribution which reduces aberrations of the projection exposure apparatus is created on a portion of the surface of the optical element during the heating in the break in operation, with the inhomogeneous temperature distribution being created by irradiating the portion with heating radiation with at least one continuous heating radiation profile formed by a beam shaping element. A related projection exposure apparatus for microlithography is disclosed.

### CROSS-REFERENCE TO RELATED APPLICATION

The present application is a continuation of, and claims benefit under 35 USC 120 to, international application No. PCT/EP2023/062496, filed May 10, 2023, which claims benefit under 35 USC 119 of German Application No. 10 2022 205 814.3, filed Jun. 8, 2022. The entire disclosure of each of these applications is incorporated by reference herein.

### FIELD

The disclosure relates to a method of operating a projection exposure apparatus for microlithography, for example for EUV lithography, comprising: heating at least one optical element, such as at least one mirror, of the projection exposure apparatus by irradiating a surface of the optical element with heating radiation during a break in operation in which the surface of the optical element is not irradiated by exposure radiation. The disclosure also relates to a projection exposure apparatus, comprising: at least one optical element, such as at least one mirror, and a heating device for irradiating a surface of the optical element, such as the mirror, with heating radiation, the heating device being designed to irradiate the surface of the optical element with heating radiation during a break in operation in which the surface of the optical element is not irradiated by exposure radiation.

### BACKGROUND

Microlithographic projection exposure apparatuses are used to produce microstructured or nanostructured components for microelectronics or microsystems technology. In order to be able to produce components having structures with extremely small dimensions on the order of nanometers and micrometers as exactly as possible, a corresponding projection exposure apparatus is capable of imaging structures arranged on a mask (reticle) exactly onto a substrate, for example a wafer.

EUV radiation at a wavelength in the EUV wavelength range has been used for several years now in order to obtain a resolution that is as high as possible, especially for lithography optical units; the wavelength generally is at 13.5 nm, while earlier systems used typical operating wavelengths of 365 nm, 248 nm or 193 nm. A consequence of the step to the EUV wavelength range is generally having to manage without refractive media, which are typically no longer able to be used meaningfully at these wavelengths, and transition to pure mirror systems operated under either virtually normal incidence or grazing incidence. With virtually normal incidence, approximately a third of the incident radiation can be absorbed on each mirror (depending on the specific incidence angle spectrum); with grazing incidence, typical absorption values are a quarter or a fifth. For comparison, in refractive media with an antireflection coating, the absorbed intensity is often on the order of parts per thousand. This can help explain the significantly more pronounced changes in the temperature in EUV optical units, which are on the order of several kelvin, in comparison with earlier systems, in which the changes in the temperature were at best a few tenths of a kelvin.

Since temperature gradients within the material of the optical element on account of the coefficient of thermal expansion of the latter can translate to surface defects or deformations on the surface of the optical element irradiated by the used or exposure radiation, these temperature gradients, especially in mirrors, can lead to significant optical aberrations which, in relation to the used wavelength, can lead to a deterioration in the imaging properties of the projection exposure apparatus. Accordingly, mirrors for EUV lithography, typically the substrates thereof, are often produced from material with a particularly low coefficient of thermal expansion, for example Zerodur® or ULE® (“ultra-low expansion” material).

These zero-expansion materials can play off component parts or phases with positive and negative coefficients of thermal expansion against one another. This can result in an effectively nonlinear relationship between thermal expansion and temperature, with there being exactly one temperature value for which the thermal expansion vanishes or is the least sensitive to changes in the temperature; to be precise, this is what is known as the zero-crossing temperature (ZCT).

During the exposure operation of the projection exposure apparatus, a mirror from the projection optical unit is usually exposed to varying radiation intensities, both locally on account of different illuminations and diffractive structures on the mask and temporally on account of different operating states. Nevertheless, it is desirable for the mean temperature of the mirror or mirror material to remain close to the zero-crossing temperature so that relatively few aberrations, which are the result of surface deformations on account of temperature gradients, are created.

In order to try to achieve this, it is known practice to use heating radiation sources which radiate heating radiation onto the surface of a respective mirror. The heating radiation sources typically operate in the infrared wavelength range (“IR heaters”) and can be used during the exposure operation, in which the surface of a respective mirror is irradiated by used radiation, and/or during a break in operation outside of the exposure operation, with the heating radiation sources being used in the latter case to preheat a respective mirror prior to the exposure operation. In order to keep the heat input during the exposure operation as constant as possible, the heating radiation sources can radiate at a high heating power when the respective mirror absorbs no exposure radiation, or only a small portion thereof, and the heating power can be reduced when the heat input by the exposure radiation increases. The IR heating radiation sources can typically irradiate only a portion of the entire surface of the optical element and thus do not supply a homogeneous temperature or temperature distribution in the entire three-dimensional main body of the optical element.

DE 10 2019 219 289 A1 describes a heating arrangement for heating an optical element, comprising: a plurality of IR emitters for irradiating an optically effective surface of the optical element with IR radiation, with these IR emitters being capable of being switched on and off independently of one another for the purpose of variably setting different heating profiles in the optical element, and at least one beam shaping unit for shaping the beam of the IR radiation steered from the IR emitters to the optically effective surface. The beam shaping unit can comprise a plurality of beam shaping segments for irradiating different segments on the optically effective surface of the optical element with IR radiation. For example, the beam shaping segments can be different regions on a diffractive optical element (DOE).

DE 10 2014 212 691 A1 and DE 10 2015 203 267 A1 describe an optical system for a lithography apparatus and a lithography apparatus, comprising: an optical element having an optical surface and temperature control unit configured to supply heat to and/or dissipate heat from the optical element in order to try to keep constant or control a deformation of the optical element during an exposure of the optical surface. In one example, the temperature control unit is configured to project temperature control points onto the optical surface, the temperature control points being able to be designed in the form of infrared light-emitting diodes, for example.

During the exposure of the optical surface, the temperature control unit can be used to (actively) control the deformation of the optical element such that the optical aberration in relation to the operating light is reduced when further aberration-relevant factors are included. The optical aberration can be measured with the aid of sensors. Should the coefficient of thermal expansion of the substrate of the optical element vary for manufacturing-related reasons, the temperature control unit can be configured to supply the heat to the optical element in a manner dependent on a measured coefficient of thermal expansion profile. In this case, the coefficient of thermal expansion profile of the optical element can be determined and stored in advance. During exposure operation, the temperature control unit can control the heat supply on the basis of the stored coefficient of thermal expansion profile.

DE 10 2015 224 281 A1 describes a method for producing a mirror for an EUV lithography apparatus, in which an expected heat flux distribution on the mirror is ascertained in a first step. In a second step, a plurality of heating zones are formed on the mirror on the basis of the ascertained heat flux distribution. In a third step, a respective heating zone is provided with a respective heating device for heating the respective heating zone on the basis of a measured temperature of the respective heating zone or the expected heat flux distribution on the mirror. In this way, the temperature should be kept constant or virtually constant in all heating zones of the mirror, in order to ensure a temperature distribution in the mirror volume that is as constant as possible. The heating zones can be preheated prior to the exposure operation, wherein different heating zones can be preheated to different extents. At least one heating device can heat a corresponding heating zone with a pattern which may comprise e.g. a ring profile or part of a ring profile. The pattern can correspond exactly to the heat flux distribution, and so the temperature can be kept constant within the heating zone. The heating device can be a resistance heater and/or a thermal emitter, which emits radiation in the infrared range or rather an IR heater head.

### SUMMARY

The disclosure seeks to provide a method of operating a projection exposure apparatus and a projection exposure apparatus with reduced aberrations.

According to a first aspect, the disclosure provides a method of operating a projection exposure apparatus in which an inhomogeneous temperature distribution which can reduce aberrations of the projection exposure apparatus, which can minimize the aberrations of the projection exposure apparatus, is created (in a targeted manner) on at least one portion (“heating zone”) of the surface of the optical element during the heating in the break in operation. The irradiated portion can be the entire surface of the optical element which is designed for reflecting the exposure radiation and which comprises a reflective coating for this purpose. However, it is also possible that the portion forms a partial area of the optically used region on the surface of the optical element. Reducing the aberrations of the projection exposure apparatus can relate to different applications which are listed hereinbelow. For example, the inhomogeneous temperature distribution can serve to reduce the aberrations of the projection exposure apparatus during the break in operation, i.e. in the case that the optical element is not irradiated by exposure radiation and the heat radiation is radiated onto the optical element.

A distinction can be made between two operating states during the operation of a projection exposure apparatus: i) an exposure operation, during which the optical elements, typically in the form of mirrors, are irradiated by exposure radiation in order to expose the substrate; and ii) a non-exposure operation in the form of a break in operation, during which no exposure radiation is present in the projection exposure apparatus. The above-described heating during the break in operation is typically followed by the exposure operation, i.e. the respective optical element is preheated during the break in operation.

The following situations (phases) might arise during the respective operating states (exposure operation or break in operation):

1) The performance of the projection exposure apparatus is (very) good, i.e. the aberrations are small, without exposure radiation, i.e. during a break in operation, and without the additional use of heating radiation.

2) The performance of the projection exposure apparatus is (very) poor with exposure radiation but without the preheating of individual or a few optical elements using heating radiation, for example because the temperature distribution of the optical element changes significantly over time (optionally by several kelvin; see above), and hence the aberrations can also change significantly over time, when the exposure radiation is switched on. For example, these changes over time might occur more quickly or cause other aberrations than can be corrected in timely fashion by other correction options of the projection exposure apparatus (e.g. by rigid body movements). Moreover, aberrations might arise on account of unsuitable material properties, e.g. variations in the mean zero-crossing temperature from optical element to optical element for production-related reasons.

To increase the imaging quality of the projection exposure apparatus, e.g. for better imaging of extremely small structures using the exposure radiation, it might be desirable to find a compromise between the two phases 1) and 2), for example in a form in which preheating by heating radiation already occurs in phase 1) as well, and the change in the temperature over time in phase 2) is reduced in this manner, for example as described in DE 10 2015 224 281 A1 cited at the outset, the entirety of which is incorporated into this application by reference.

DE 10 2015 224 281 A1 proposes to keep the temperature constant or virtually constant in all heating zones of the mirror during the exposure operation, in order to help ensure a temperature distribution of the mirror volume that is as constant as reasonably possible. The heating zones can be preheated before the exposure operation so that the zero-crossing temperature is approximately set or obtained on a respective heating zone. The respective heating zone is kept as permanently as possible on or in the neighborhood of the zero-crossing temperature in this way, inter alia in order to reduce temporal changes in the mean temperature in the respective heating zone in the case of alternating modes of operation. Both simulations and measurements have confirmed that the use of such preheating of a respective optical element in a respective heating zone can significantly improve the imaging quality of the projection exposure apparatus.

However, it has turned out that the creation of a homogeneous (constant) temperature in the respective heating zone by preheating can lead to unwanted deteriorations in the imaging quality of the projection exposure apparatus during phase 2), i.e. during the exposure operation. These deteriorations were accepted in the past; inter alia, they can be traced back to the fact that the optical element generally is preheated inhomogeneously in order to create a homogeneous temperature in the respective heating zone. Even in the case of a homogeneous temperature distribution in the respective heating zone, the latter still has a spatially dependent deformation of the optical element, albeit one that is significantly reduced in comparison with an inhomogeneous temperature distribution in the respective heating zone. Additionally, individual properties of the optical element that can be traced back to material and manufacturing variations during the production of the optical element are not taken into account during the preheating with the aid of a homogeneous temperature distribution and might contribute to aberrations in phase 2).

It was also observed that the deformation of optical elements can depend strongly on the manner in which different portions of the optical element are heated. It is typically not the case that all surface regions of an optical element are accessible from the outside for heating purposes; in any case, the entire volume of an optical element generally cannot be heated to a three-dimensionally homogeneous temperature. In general, portions of the optical element, for example the entire optically used surface region, being heated homogeneously is not optimal for the imaging quality of the projection exposure apparatus. It might be significantly more desirable to provide a respective portion with an inhomogeneous temperature distribution.

The disclosure therefore proposes not to set or create a homogeneous temperature distribution in the respective portion irradiated by the heating radiation but to set or create a targeted inhomogeneous temperature distribution instead.

The inhomogeneous temperature distribution on the at least one portion can reduce the aberrations of the projection exposure apparatus vis-à-vis a homogeneous temperature distribution on the at least one portion. A typical assumption made during the comparison between the inhomogeneous and the homogeneous temperature distribution is that the homogeneous temperature distribution has a temperature that is constant over the portion and corresponds to the temperature of the inhomogeneous temperature distribution when averaged over the portion. In this case, the inhomogeneous temperature distribution is chosen such that aberrations of the projection exposure apparatus are reduced—in comparison with a heating of the portion with a homogeneous temperature distribution. The aberrations that are reduced can be wavefront aberrations for example. The aberrations or wavefront aberrations that are reduced can be traced back to e.g. manufacturing variations, the preheating itself, an inhomogeneous spatial distribution of the exposure radiation to be expected during the subsequent exposure operation, etc. The aberrations or wavefront aberrations to be corrected are e.g. known from measurements or can be estimated with the aid of predictions (e.g. in the case of the spatial distribution of the exposure radiation to be expected).

Various effects can be better corrected by the targeted inhomogeneous temperature distribution than by a homogeneous temperature distribution. For example, the respective optical element can be temperature controlled in advance (good for phase 2) without impairing the performance in phase 1) (too much). Moreover, targeted inhomogeneous preheating can allow the performance, i.e. the imaging quality, of the projection exposure apparatus to also be improved beyond the above-described state that no heating radiation sources are used in phase 1).

In one variant of the method, a mean temperature of the inhomogeneous temperature distribution in the portion of the surface deviates by no more than ±1.5 K, such as by no more than ±0.5 K, from a zero-crossing temperature of the optical element. The zero-crossing temperature of the optical element is understood to mean the zero-crossing temperature of the material of the main body or substrate from which the optical element is formed. In this case, the substrate or main body material is a zero-expansion material, for example doped quartz glass, specifically titanium-doped quartz glass, as is commercially available under the trade name ULE®, or a glass ceramic, for example Zerodur®.

Typically, the zero-crossing temperature of the material is substantially constant within the volume of the substrate, and hence also in the portion on the surface of the substrate, i.e. spatially dependent deviations are small. For the considerations set forth below, the spatially dependent deviations are generally negligible, and so the zero-crossing temperature in the portion or on the entire optically used surface of the optical element is considered constant for the considerations set forth below. As described above, it can be desirable for the heated portion to be heated to approximately the zero-crossing temperature by the preheating since the optical element is least sensitive to changes in the temperature at or in the neighborhood of the zero-crossing temperature. As likewise described above, the creation of a homogeneous temperature which is constant over the portion and (substantially) corresponds to the zero-crossing temperature does not necessarily lead to minimal aberrations of the projection exposure apparatus during the break in operation; rather, it may be desirable to deviate from a homogeneous temperature distribution in the portion in a targeted manner in order to bring about a targeted deformation. The extent to which the mean temperature of the inhomogeneous temperature distribution is allowed to deviate from the zero-crossing temperature depends, inter alia, on the heating power of the incident EUV radiation and on the material characteristics of the optical element. The specified values of 1.5 K and 0.5 K are guidelines. In certain applications it might be desirable to allow a greater deviation than the values specified.

In a variant, the method comprises: determining the inhomogeneous temperature distribution which reduces or minimizes the aberrations of the projection exposure apparatus, with individual material-specific properties of the optical element on which the inhomogeneous temperature distribution is created being taken into account when determining the inhomogeneous temperature distribution.

In general, the inhomogeneous temperature distribution can be determined in advance or else during the operation of the projection exposure apparatus (“live”) for different applications.

For example, possible applications are:

a) The projection exposure apparatus already has certain aberrations when neither exposure radiation nor heating radiation (e.g. for preliminary temperature control to approximately the zero-crossing temperature; see above) are present.

b) The projection exposure apparatus already has certain aberrations when there is no exposure radiation, but heating radiation is already used (e.g. for preliminary temperature control to approximately the zero-crossing temperature; see above).

c) The projection exposure apparatus has certain aberrations when operated with exposure radiation. Optionally, a temperature input by heating radiation may be present in addition to the exposure radiation, even during the exposure operation.

d) The projection exposure apparatus has certain aberrations (with or without thermal loads) which differ from other projection exposure apparatuses of the same type (tool-to-tool variation).

In this context, the above-described applications partially agree with the above-described phases 1) and 2), with a) corresponding to phase 1) and c) corresponding to phase 2); b) represents an intermediate state. Further applications can be desirable.

An inhomogeneous temperature profile which reduces or minimizes the associated aberrations (e.g. deformations or wavefront aberrations) can be determined for each of the above-described applications. It is also possible to add a plurality of aberrations and determine an inhomogeneous temperature profile which reduces or minimizes the sum of aberrations. For example, application d) can be combined with one of applications a) to c) in order to correct both aberrations of the projection exposure apparatus which can be traced back to manufacturing inaccuracies when producing a plurality of projection exposure apparatuses of the same type and aberrations that occur in the same way for all projection exposure apparatuses of the same type. For example, individual material-specific properties of the substrate of the optical element can be considered in case d), the material-specific properties being able to be traced back to manufacturing variations during the production of the optical element and distinguishing the optical element of the projection exposure apparatus from another optical element of the same type.

For example, the inhomogeneous temperature distribution can be determined by simulation, optionally with inclusion of individual material-specific properties of the relevant optical element, for example an averaged distribution of the zero-crossing temperature of the main body or the substrate of the optical element on which the inhomogeneous temperature profile is created, the distribution of zero-crossing temperature also being determined with spatial resolution in an optional alternative. In general, a feedforward model is used in application c) for the expected spatially dependent radiation distribution during the exposure operation.

The inhomogeneous temperature distribution can also be determined experimentally, for example by varying different heating powers when the optical element is irradiated by the heating radiation, wherein the heating power can also vary in spatially dependent fashion or the optical element is irradiated by different heating radiation profiles and the aberrations created in the process are measured. Rather than measuring (wavefront) aberrations with the aid of suitable measuring devices, it is also possible to conduct measurements of the temperature distribution of the optical element, e.g. with the aid of an IR camera, or measurements of the surface deformation of the optical element and to use the measurements for the determination of the inhomogeneous temperature profile.

The correction of the aberrations (such as wavefront aberrations) described in the above-described applications does not necessarily require targeted inhomogeneous heating of precisely the optical element or optical elements which create the wavefront aberrations with the heating radiation, which create the aberrations. Targeted heating for creating an inhomogeneous temperature profile might (but need not) be carried out on other optical elements as well (use of compensation effects within the projection exposure apparatus). In this case, the aberrations to be corrected might arise due to thermal effects but also due to other material deformations or changes in the positions of the components and might also originate from non-optical components.

In one variant, the inhomogeneous temperature distribution reduces or minimizes aberrations in the form of wavefront aberrations which are created on the portion of the surface when the optical element is heated during the break in operation. This variant can correspond to the above-described application b): as described there, aberrations which can be compensated by the inhomogeneous temperature distribution arise when the portion is heated to a mean temperature which approximately corresponds to the zero-crossing temperature of the optical element. Preheating of the optical element is typically implemented from a reference temperature, which can be at e.g. 22° C., to the mean temperature which approximately corresponds to the zero-crossing temperature. In this case, the wavefront aberrations can arise on account of the inhomogeneous heat flux distribution in the optical element, on account of material variations during the production of the optical element, on account of manufacturing influences during the production of the optical element, etc. The inhomogeneous temperature distribution can serve to largely correct or minimize these wavefront aberrations.

It is understood that the inhomogeneous temperature distribution can additionally be designed to reduce or minimize the aberrations or wavefront aberrations of the projection exposure apparatus or optical element which are present without the optical element being irradiated by the heating radiation. This can correspond to the above-described application a). The inhomogeneous temperature distribution suitable for this purpose can be determined in the manner described above, for example by virtue of measuring the (individual) wavefront aberrations of the optical element. In this case, the wavefront aberrations described in case d), which can be traced back to material variations in the (glass) blank (“boule”) or to manufacturing influences, can also be measured and taken into account. Optionally, the manufacturing influences on the respective mirrors of different projection exposure apparatuses of the same type are similar, with the result that the desired inhomogeneous temperature distribution of the optical element is known at an early stage. In this way, a beam shaping element can be suitably designed at an early time in order to create the inhomogeneous temperature distribution via a suitable heating radiation profile. A certain flexibility within the scope of creating a desired inhomogeneous temperature distribution is present in any case provided that the beam shaping element comprises a sufficient number of degrees of freedom, for example in the form of a plurality of separately controllable segments. As described above, it is also possible that the wavefront aberrations created at one optical element are corrected in full or in part on (at least) one other optical element.

In one variant, the inhomogeneous temperature distribution is created by irradiating the portion with heating radiation with at least one continuous heating radiation profile formed by at least one beam shaping element. The continuous heating radiation profile can be created with the aid of a suitable beam shaping element, for example with the aid of a diffractive optical element or with the aid of a portion (segment) of a diffractive optical element. The diffractive optical element can be matched on an individual basis to the material properties of the optical element, for example the mirror, which is used in the projection exposure apparatus and which is irradiated by the heating radiation. Different inhomogeneous temperature distributions and hence also different diffractive optical elements can be used for different projection exposure apparatuses of the same type. However, this is not mandatory since the manufacturing influences during the production of the respective mirrors are optionally similar (see above), and so the same diffractive optical elements can optionally be used as beam shaping elements for different projection exposure apparatuses of the same type. Typically, a respective beam shaping element is designed to create a fixedly predefined heating radiation profile. A heating radiation profile is understood to mean a heat flux density distribution created by the respective beam shaping element in combination with a heating radiation source.

To create the inhomogeneous temperature distribution, it is possible to use a single continuous heating radiation profile with which the portion is irradiated. However, it is also possible that the portion of the surface is irradiated by two or more heating radiation profiles created by two or more beam shaping elements. In this case, a respective region larger than the portion of the surface can be irradiated by the heating radiation profiles, for example, and these overlap in the portion of the surface in order to create the inhomogeneous temperature profile.

Since the above-described applications may occur gradually during the use of the projection exposure apparatus, the inhomogeneous temperature distributions to be set can in each case also change over time (within the same projection exposure apparatus), i.e. different inhomogeneous temperature profiles can be set depending on the application. When alternating between the applications, it might be desirable to keep the heating power of the heating radiation or the inhomogeneous temperature distribution constant, as described below.

In one variant, a heating power of the heating radiation for creating the inhomogeneous temperature distribution during the break in operation is maintained during a subsequent exposure operation of the projection exposure apparatus, with exposure radiation irradiating the surface of the optical element during the exposure operation. During the heating in the break in operation, a stationary state, in which the (stationary) inhomogeneous temperature distribution (preheating temperature) is created on the optical element, is attained after a certain amount of time. The heating power introduced into the optical element during the break in operation in one of the two applications a) and b) is fixed in this case, i.e. it is maintained even if additional thermal loads (for example in the form of exposure radiation) are created at the respective optical element. In general, fixing or maintaining the heating power can reduce the control complexity during the exposure operation and leads to a stationary state, in which the inhomogeneous temperature distribution is attained again, being attained comparatively quickly again during a further break in operation following the exposure operation.

In a variant, the heating power of the heating radiation during the break in operation is modified during a subsequent exposure operation, during which exposure radiation irradiates the surface of the optical element, in order to maintain the inhomogeneous temperature distribution in the portion of the surface (as far as possible). It can be desirable to maintain the inhomogeneous temperature distribution created or set during the break in operation during the exposure operation as well. In order to attain this, it is generally desirable to modify the heating power of the heating radiation on account of the heat input into the optical element due to the exposure radiation. In this case, the heating power of the heating radiation is modified using the degrees of freedom present when providing the heating radiation or from the available heating radiation sources (see below), in such a way that the sum of all thermal loads on the optical element corresponds to the best possible extent to the inhomogeneous temperature distribution created during the preheating during the break in operation. For example, this can be attained by virtue of the mean temperature of the entire surface being kept as constant as possible or by virtue of less heating radiation than was the case during the preheating being supplied to the regions of the surface that are heated by the exposure radiation. In order to enable this, the corresponding regions which are heated by the exposure radiation is subjected to a sufficient amount of preliminary temperature control during the preheating.

Should such a reduction in the heating power of the heating radiation be possible for a plurality of different operating modes and exposure radiation distributions on the surface of the optical element, the preheating should be designed accordingly for a “common” profile of the inhomogeneous temperature distribution, i.e. it should contain sufficiently large heating in different regions of the surface of the optical element.

A further aspect of the disclosure relates to a projection exposure apparatus in which, for reducing aberrations of the projection exposure apparatus, the heating device is designed or programmed to create an inhomogeneous temperature distribution on at least one portion of the surface of the optical element during the heating in the break in operation, with the inhomogeneous temperature distribution on the at least one portion reducing the aberrations of the projection exposure apparatus in comparison with a homogeneous temperature distribution on the at least one portion.

The projection exposure apparatus can be an EUV lithography apparatus but might also relate to a UV lithography apparatus which is operated with UV radiation in a wavelength range of less than approximately 370 nm. The heating device can comprise at least one heating radiation source for creating the heating radiation or irradiating the portion of the surface. The heating radiation source can be designed to create a predefined heating power when activated. However, it is also possible that the heating power of the heating radiation source is continuously adjustable. The heating device is designed or contains a programmable controller for controlling the at least one heating radiation source in order to activate the latter during a break in operation (as well) in order to create the inhomogeneous temperature distribution on the at least one portion of the surface.

In one embodiment, the heating device is designed or programmed to create a mean temperature of the inhomogeneous temperature distribution in the portion of the surface which deviates by no more than ±1.5 K, such as by no more than ±0.5 K, from a zero-crossing temperature of the optical element. As described above, it is generally desirable to preheat the optical element to approximately the zero-crossing temperature of the optical element prior to the exposure operation, in order to help reduce the aberrations in the exposure operation.

In an embodiment, the heating device for creating the inhomogeneous temperature distribution comprises at least one heating radiation source for creating heating radiation and at least one beam shaping element for creating a continuous heating radiation profile. The use of a continuous heating radiation profile as created by a beam shaping element in the form of a diffractive optical element, for example, can be desirable to create the inhomogeneous temperature distribution. The heating radiation source can be an IR radiation source, for example an IR laser, an IR diode or the like.

The heating device can be designed in different ways. For example, the heating device can be designed as in DE 10 2019 219 289 A1 cited above, the entirety of the latter being incorporated into this application by reference. For example, the heating device might comprise a plurality of heating light sources in the form of IR emitters, which can be switched on and off independently of one another in order to create different heating radiation profiles. As described in DE 10 2019 219 289 A1, a plurality of beam shaping elements or beam shaping segments of one and the same diffractive optical element can be used to create a respective individually adapted inhomogeneous temperature distribution on different portions of the surface of the optical element. Alternatively, use can be made of a plurality of heater heads, which each create only one heating radiation profile of the heating radiation with which a respective portion of the surface of the optical element is irradiated. However, the use of a heating device or a heater head capable of creating a plurality of heating radiation profiles is generally more desirable since this involves far less installation space for the same number of available degrees of freedom.

It is also possible that the heating device is designed to irradiate spatially overlapping (common) portions on the surface of the optical element with the heating radiation created by two or more beam shaping elements, with the result that the heating radiation profiles overlap in space. As a result of the common portion being irradiated sequentially or simultaneously by the heating radiation, different heating radiation profiles can be created there. The (inhomogeneous) temperature distribution in the respective portion arises from the heating radiation profile, i.e. the intensity distribution of the heating radiation on the surface of the optical element in the respective portion, in combination with the material properties of the optical element and the thermal boundary conditions of the entire projection exposure apparatus.

The above-described heating device can be used not only during a break in operation but also during the exposure operation to optimize the inhomogeneous temperature distribution, i.e. not only the mean value of the temperature, in the respective portion in respect of aberrations or wavefront aberrations and to adapt the inhomogeneous temperature distribution to different modes of operation of the projection exposure apparatus, in which different thermal loads, which can thus be compensated for, are created in each case in the respective portion.

In general, it is possible to irradiate the entire optically used portion of the optical element using a heating device which comprises only one heating radiation source for creating heating radiation and only one beam shaping element for creating exactly one heating radiation profile. In this case, it can be desirable for the beam shaping element, which is typically in the form of a diffractive optical element, to have a very pronounced adaptation to the boundary conditions of the respective projection exposure apparatus, for example to the individual expansion behavior of the optical element, e.g. to its zero-crossing temperature, to the EUV and IR reflectivity of the respective optical element, to the pressure conditions within the projection exposure apparatus, etc. However, the correction options in this case can be strongly coupled to the boundary conditions and predefined aberrations to be corrected. By contrast, on account of the greater number of degrees of freedom, the heating device described in DE 10 2019 219 289 A1 may also allow a certain degree of response to changes in the boundary conditions or changes in the aberrations to be corrected even during the exposure operation of the projection exposure apparatus, without the heating device or its components, for example the beam shaping equipment, being replaced for this purpose.

In general, it is also possible for the heating device to additionally comprise at least one piece of heating equipment which is designed to create a homogeneous heating radiation profile, i.e. a piece of heating equipment designed to create a homogeneous heat flux density distribution in the portion of the surface of the optical element.

In a further embodiment, the heating device is designed either to maintain, during a subsequent exposure operation of the projection exposure apparatus, a heating power of the heating radiation used to create the inhomogeneous temperature distribution during the break in operation or to modify, during the subsequent exposure operation, the heating power of the heating radiation used to create the inhomogeneous temperature distribution during the break in operation in order to maintain the inhomogeneous temperature distribution in the portion of the surface during the exposure operation. As described above, it might be desirable during the exposure operation to maintain the heating power of the heating radiation which led to the inhomogeneous temperature distribution during the break in operation. Alternatively, the heating power can be modified during the exposure operation, in such a way that the inhomogeneous temperature distribution created during the break in operation is also maintained during the exposure operation.

Further features and aspects of the disclosure will be apparent from the description of working examples of the disclosure that follows, with reference to the figures of the drawing, which show certain details of the disclosure, and from the claims. The individual features can be implemented individually in their own right or collectively in any combination in a variant of the disclosure.

### BRIEF DESCRIPTION OF THE DRAWINGS

Exemplary embodiments are illustrated in the schematic drawings and are explained in the following description. In the drawings:

FIG. 1 schematically shows a meridional section of a projection exposure apparatus for EUV projection lithography;

FIGS. 2A-2B show schematic illustrations of an optical element from the projection exposure apparatus in FIG. 1 and of a heating device for heating the optical element during a break in operation and during an exposure operation;

FIGS. 3A-3B show schematic illustrations of three portions of the surface of the optical element with three heating radiation profiles and three inhomogeneous temperature distributions which emerge from the heating radiation profiles; and

FIG. 4 shows schematic illustrations of wavefront aberrations of the optical element in the case of a homogeneous temperature distribution and in the case of an inhomogeneous temperature distribution in one of the portions.

### DETAILED DESCRIPTION

In the description of the drawings that follows, identical reference signs are used for components that are the same or have the same function.

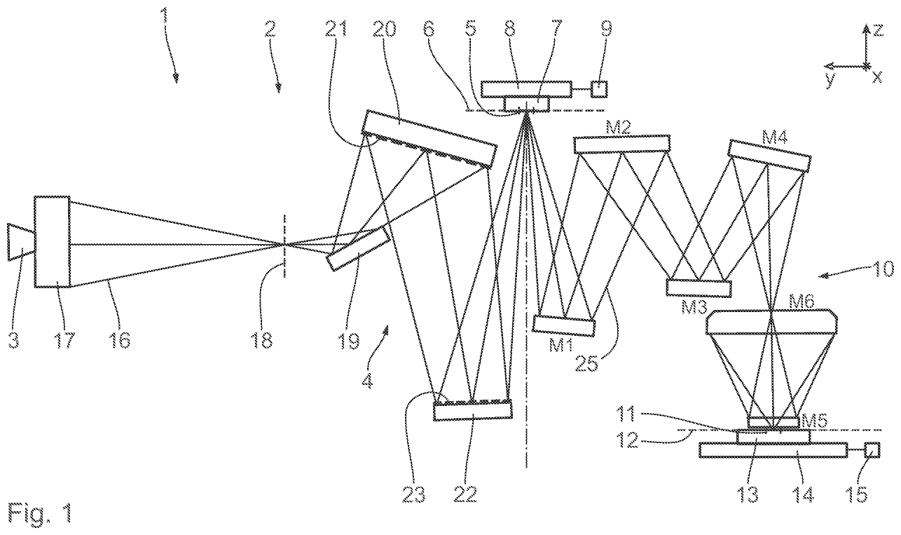

There follows a description with reference to FIG. 1 by way of example of certain constituent parts of an optical arrangement for EUV lithography in the form of a projection exposure apparatus 1 for microlithography. The description of the basic setup of the projection exposure apparatus 1 and the constituent parts thereof should not be considered here to be restrictive.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided in the form of a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable via a reticle displacement drive 9, such as in a scanning direction.

For explanation purposes, a Cartesian xyz-coordinate system is depicted in FIG. 1. The x-direction runs perpendicularly into the plane of the drawing. The y-direction runs horizontally, and the z-direction runs vertically. The scanning direction runs in the y-direction in FIG. 1. The z direction runs perpendicularly to the object plane 6.

The projection exposure apparatus 1 comprises a projection system 10. The projection system 10 is used to image the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, such as in the y-direction. The displacement of the reticle 7 on the one hand by way of the reticle displacement drive 9 and of the wafer 13 on the other hand by way of the wafer displacement drive 15 may be synchronized.

The radiation source 3 is an EUV radiation source. The radiation source 3 emits EUV radiation 16, which is also referred to below as used radiation, illumination radiation or illumination light. For example, the used radiation has a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector mirror 17. The collector mirror 17 can be a collector mirror with one or more ellipsoidal and/or hyperboloidal reflection surfaces. The illumination radiation 16 can be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 can be structured and/or coated, firstly, for optimizing its reflectivity for the used radiation and, secondly, for suppressing extraneous light.

Downstream of the collector mirror 17, the illumination radiation 16 propagates through an intermediate focus in an intermediate focal plane 18. The intermediate focal plane 18 can constitute a separation between a radiation source module, comprising the radiation source 3 and the collector mirror 17, and the illumination optical unit 4.

The exposure optical unit 4 comprises a deflection mirror 19 and, downstream thereof in the beam path, a first facet mirror 20. The deflection mirror 19 can be a plane deflection mirror or, alternatively, a mirror with a beam-influencing effect going beyond the pure deflection effect. In an alternative to that or in addition, the deflection mirror 19 can be designed as a spectral filter that separates a used light wavelength of the illumination radiation 16 from extraneous light at a different wavelength. The first facet mirror 20 comprises a plurality of individual first facets 21, which are also referred to below as field facets. FIG. 1 illustrates only some of the facets 21 by way of example. In the beam path of the illumination optical unit 4, a second facet mirror 22 is disposed downstream of the first facet mirror 20. The second facet mirror 22 comprises a plurality of second facets 23.

The illumination optical unit 4 thus forms a double-faceted system. This basic principle is also referred to as a fly's eye integrator. The individual first facets 21 are imaged into the object field 5 using the second facet mirror 22. The second facet mirror 22 is the last beam-shaping mirror or else actually the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection system 10 is a doubly obscured optical unit. The projection optical unit 10 has an image-side numerical aperture which is greater than 0.3 or 0.5 and which can also be greater than 0.6 and which can be for example 0.7 or 0.75.

Just like the mirrors of the illumination optical unit 4, the mirrors Mi can have a highly reflective coating for the illumination radiation 16.

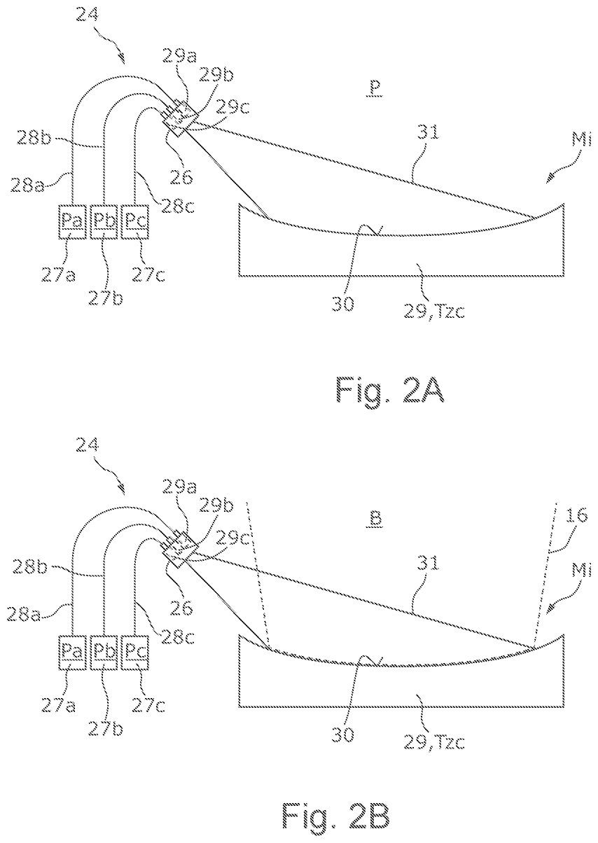

FIGS. 2A-2B show, by way of example, one of the six mirrors Mi of the projection optical unit 10 from the projection exposure apparatus 1 in FIG. 1 and a heating device 24. In the example shown, the heating device 24 comprises three heating radiation sources 27a-c, which are designed as IR lasers and which are connected via a respective fiber 28a-c to a heater head 26 of the heating device 24. Three pieces of beam shaping equipment in the form of diffractive optical elements 29a-c, which are only indicated in FIGS. 2A-2B, are arranged in the heater head 26. The heater head 26 serves to irradiate the mirror Mi, more precisely a surface 30 of the mirror Mi formed on the top side of a substrate 29 of the mirror Mi, with heating radiation 31. For example, the heating device 24 shown in FIGS. 2A-2B can be designed as described in DE 10 2019 219 289 A1.

In the example shown, the substrate 29 is formed of titanium-doped quartz glass, more precisely ULE®, which has a zero-crossing temperature T_{ZC}. To simplify matters, the zero-crossing temperature T_{ZC} of the substrate 29 is considered to be constant over the volume of the substrate 29 hereinbelow; however, it generally has minor manufacturing-related variations in the volume of the substrate 29.

FIG. 2A shows the optical element Mi during a break in operation P, during which the surface 30 of the substrate 29 is not irradiated by EUV radiation. FIG. 2B shows the optical element Mi during the exposure operation B of the projection exposure apparatus 1, in which EUV radiation 16 irradiates the surface 30 of the substrate 29. Although not depicted in FIGS. 2A-2B, a highly reflective coating serving to reflect the EUV radiation 16 has been applied to the top side of the substrate 29. In the example shown, the reflective coating comprises a plurality of alternating layers of silicon and molybdenum.

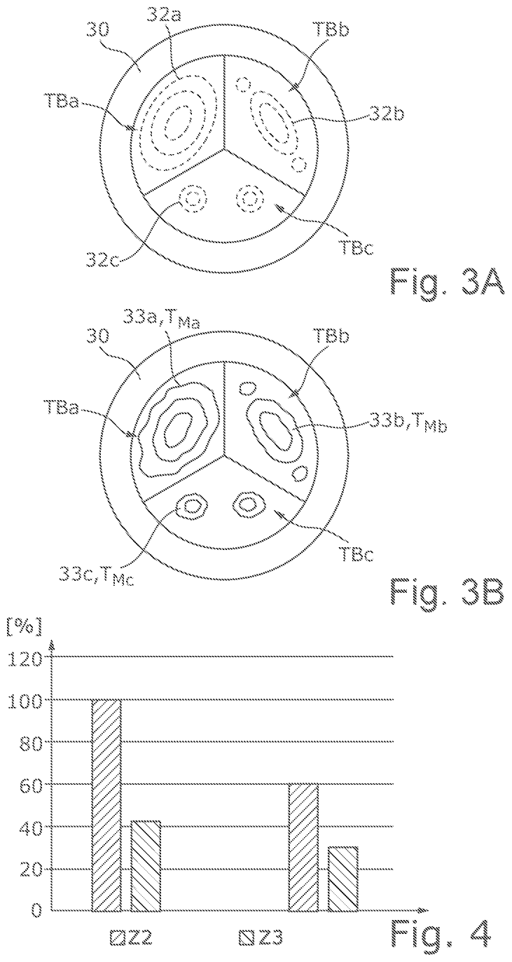

As evident from FIG. 3A, three portions TBa-c of the surface 30 are irradiated by the heating radiation 31, with the outer contours of the portions corresponding to the region of the surface 30 of the mirror Mi, shown in FIGS. 2A-2B and circular in the example shown, irradiated by the EUV radiation 16. In the example shown, the three portions Tba-c are designed as circular sectors and extend over an angle of 120° in each case. It is self-evident that this is not mandatory and that the portions Tba-c might have a different geometry and, for example, need not be of the same size. It is also possible for the three portions Tba-c together to cover a larger or smaller area than the region of the surface 30 irradiated by the EUV radiation 16, especially since the size and shape of the region of the surface 30 irradiated by the exposure radiation in the form of the EUV radiation 16 might change depending on the illumination settings of the projection exposure apparatus 1.

FIG. 3A very schematically shows the lines of equal intensity of an intensity distribution or of a respective continuous heating radiation profile 32a-c of the heating radiation 31 which irradiates the surface 30 of the mirror Mi coming from the heater head 26. In this case, a respective heating radiation profile 32a-c is created by one of the three beam shaping elements 29a-c, which are housed in the heater head 26 and assigned to a respective heating radiation source 27a-c. The three heating radiation sources 27a-c can be switched on and off independently of one another. A controller of the heating device 24 not depicted here can serve control purposes; this controller may be suitable hardware and/or software, for example in the form of a control computer. Switching the heating radiation sources 27a-c on and off allows the three portions Tba-c to be irradiated independently of one another and by a different heating radiation profile 32a-c in each case, as evident from FIG. 3A. In this case, a respective heating radiation profile 32a-c is fixedly predefined by the respective beam shaping element 29a-c and can typically no longer be modified during the operation of the projection exposure apparatus 1.

An inhomogeneous temperature distribution 33a-c in the respective portion Tba-c, which is depicted in FIG. 3B, arises from the heating radiation profile 32a-c, i.e. the intensity distribution of the heating radiation 31 on the surface 30 of the mirror Mi in the respective portion Tba-c, in combination with the material properties of the mirror Mi and the thermal boundary conditions of the entire projection exposure apparatus 1. As evident from FIG. 3B, in which exemplary lines of equal temperature are shown, the inhomogeneous temperature distribution 33a-c in a respective portion Tba-c differs for the aforementioned reasons from the radiated-in heating radiation profile 32a-c, which is depicted in FIG. 3A.

The inhomogeneous temperature distribution 33a-c, which is created in the respective portion Tba-c during the break in operation P, is designed or chosen such that this enables a reduction, such as a minimization, of aberrations of the projection exposure apparatus 1. In the example shown, it is possible to set the heating power Pa, Pb, Pc of the respective heating radiation source 27a-c, whereby the inhomogeneous temperature distribution 33a-c can be modified in the respective portion TBa-c. The assumption is made hereinbelow that the heating power Pa, Pb, Pc of the three heating radiation sources 27a-c is constant or kept constant and that a stationary operating state, in which the inhomogeneous temperature distribution 33a-c does not change over time, has set in during the break in operation P.

The inhomogeneous temperature distribution 33a-c on the respective portion Tba-c can be designed or optimized for different applications in which the aberrations of the projection exposure apparatus 1 can in each case be reduced or, in the ideal case, minimized during the break in operation P and/or during the exposure operation B.

In the example shown in FIGS. 3A-3B, the inhomogeneous temperature distribution 33a-c is chosen or defined in such a way in the respective portion Tba-c that these aberrations of the projection exposure apparatus 1, which are already created by the mirror Mi, are reduced when neither heating radiation 31 nor exposure radiation 16 is radiated onto the mirror Mi. Moreover, the aberrations arising from the mirror Mi being heated from a reference temperature, usually room temperature (22° C.), to a mean temperature T_{Ma}, T_{Mb}, T_{Mc} averaged over the respective portion Tba-c are also reduced.

On account of a suitable design of the heating device 24, the mean temperature T_{Ma}, T_{Mb}, T_{Mc} of the inhomogeneous temperature distribution 33a-c in the respective portion Tba-c of the surface 30 is defined such that it does not deviate from the zero-crossing temperature T_{ZC} of the substrate 29 of the optical element Mi by more than ±1.5 K, and typically does not deviate by more than ±0.5 K. It is not mandatory for the mean temperature T_{Ma}, T_{Mb}, T_{Mc} of the inhomogeneous temperature distribution 33a-c to be located within the specified interval around the zero-crossing temperature T_{ZC}. The inhomogeneous temperature distribution 33a-c indicated in FIG. 3B moreover allows the correction of wavefront aberrations of the mirror Mi which can be traced back to individual material properties of precisely this mirror Mi; these are wavefront aberrations which occur only for this mirror Mi and not for other mirrors of the same type that are used in other projection exposure apparatuses 1 of the same type.

The inhomogeneous temperature distribution 33a-c created on the respective portions Tba-c allows wavefront aberrations to be reduced in comparison with a homogeneous temperature distribution in the respective portions Tba-c, wherein, in the case of the homogeneous temperature distribution, a respective portion Tba-c is heated constantly to the mean temperature T_{Ma}, T_{Mb}, T_{Mc} of the inhomogeneous temperature distribution 33a-c.

FIG. 4 shows aberrations in the form of wavefront aberrations which are expressed in the form of Zernike coefficients Z2, Z3 and which were averaged over the three portions Tba-c in the example shown. FIG. 4, left, depicts the wavefront aberrations Z2, Z3 which are created in the case of a homogeneous temperature distribution on the three portions Tba-c, while FIG. 4, right, depicts the wavefront aberrations Z2, Z3 which arise in the case of the inhomogeneous temperature distribution 33a that is depicted in FIG. 3B. It is clearly evident that the inhomogeneous temperature distribution 33a significantly reduces the wavefront aberrations Z2, Z3 vis-à-vis a homogeneous temperature distribution in the three portions Tba-c.

In the example described further above, the wavefront aberrations Z2, Z3 were optimized for a stationary operating state during a break in operation P, in which the mirror Mi was heated on average to a desired pre-heating temperature which approximately corresponds to the zero-crossing temperature T_{ZC}. It is evident that additional aberrations occur during the exposure operation B on account of the exposure radiation 16 being radiated in. The heating device 24 can also be used to reduce the aberrations arising during the exposure operation B. Various options exist in this respect:

It is possible to maintain the heating power Pa, Pb, Pc of the heating radiation 31 for creating the inhomogeneous temperature distribution 33a-c during the break in operation P during the subsequent exposure operation B of the projection exposure apparatus 1. The heating radiation profiles 32a-c depicted in FIG. 3A are also created in the respective portions Tba-c during the exposure operation B but in the exposure operation B the temperature profiles on the respective portions Tba-c no longer correspond to the inhomogeneous temperature profiles 33a-c depicted in FIG. 3B on account of the heat input by the exposure radiation 16.

Alternatively, it is possible that the heating power Pa, Pb, Pc of the heating radiation 31, which led to the creation of the inhomogeneous temperature distribution 33a-c during the break in operation P, is modified by the heating device 24 during the subsequent exposure operation B in order to ideally maintain the respective inhomogeneous temperature distribution 33a-c, as specified during the break in operation P, in the portion Tba-c of the surface 30 (cf. FIG. 3B). The three heating powers Pa, Pb, Pc of the heating radiation sources 27a-c can be suitably modified for this purpose. In both cases, the aberrations of the projection exposure apparatus 1 can also be reduced by the heating device 24 during the exposure operation B.

The inhomogeneous temperature distribution 33a-c which reduces the aberrations of the projection exposure apparatus 1 can be determined in different ways in the respective portion Tba-c. For example, the inhomogeneous temperature distribution 33a-c can be determined by simulations, optionally with the inclusion of individual material-specific properties of the relevant mirror Mi, for example taking account of an averaged distribution of the zero-crossing temperature T_{ZC} of the substrate 29 of the mirror Mi, the distribution of zero-crossing temperature also being determined with spatial resolution in an optional alternative. The inhomogeneous temperature distribution 33a-c can also be determined experimentally, for example by varying different heating powers Pa, Pb, Pc when the mirror Mi is irradiated by the heating radiation 31, wherein, optionally experimentally, the mirror Mi is irradiated by heating radiation 31 with different heating radiation profiles, and the aberrations created in the process are measured. Rather than measuring (wavefront) aberrations Z2, Z3, . . . with the aid of suitable measuring devices, e.g. via a Shack-Hartmann sensor, it is also possible to conduct measurements of the temperature distribution of the mirror Mi, e.g. with the aid of an IR camera, or measurements of the surface deformation of the mirror Mi and to use the measurements for the determination of the inhomogeneous temperature profile 33a-c.

The inhomogeneous temperature distribution 33a-c can also serve to reduce aberrations of the projection exposure apparatus 1 which do not arise as a result of the mirror Mi itself, but which can be traced back to other effects (use of compensation effects within the projection exposure apparatus). In this case, the aberrations to be corrected might arise due to thermal effects, due to other material deformations or due to changes in the positions of the components and might also originate from non-optical components.

It is evident that a greater or smaller number of portions TBa, TBb, TBc, . . . might be present on the surface 30 of the mirror Mi, with each of the portions being irradiated by heating radiation 31 with an individual heating radiation profile 32a, 32b, 32c, . . . . For example, the heating device 24 might comprise only one heating radiation source for creating heating radiation 31 with a single heating radiation profile, which is created on the surface 30 of the mirror Mi. Alternatively, it is possible that the heating device 24 is designed to create a plurality of heating radiation profiles 32a, 32b, 32c, . . . on the surface 30 of the mirror Mi, the heating radiation profiles overlapping one another or being overlaid on one another in part.

What is claimed is:

1. A method of operating a microlithography projection exposure apparatus comprising an optical element comprising a surface, the method comprising:
during a break in operation of the microlithography projection exposure apparatus when the surface of the optical element is not irradiated by exposure radiation, irradiating the portion of the surface of the optical element with a continuous heating radiation formed by a beam shaping element, thereby heating the optical element to create an inhomogeneous temperature distribution on the portion of the surface of the optical element to reduce aberrations of the projection exposure apparatus,
wherein the beam shaping element comprises a diffractive optical element or a portion of a diffractive optical element.

2. The method of claim 1, wherein the optical element comprises a mirror.

3. The method of claim 1, wherein the microlithography projection exposure apparatus comprises an EUV microlithography projection exposure apparatus.

4. The method of claim 1, wherein the inhomogeneous temperature distribution on the portion of the surface of the optical element reduces the aberrations of the microlithography projection exposure apparatus compared with aberrations present when the portion of the surface of the optical element has a homogeneous temperature distribution.

5. The method of claim 1, wherein a mean temperature of the inhomogeneous temperature distribution of the portion of the surface of the optical deviates by no more than ±1.5 K from a zero-crossing temperature of the optical element.

6. The method of claim 5, wherein the inhomogeneous temperature distribution reduces aberrations in the form of wavefront aberrations created on the portion of the surface of the optical element when the optical element is heated to the mean temperature during the break in operation of the microlithography projection exposure apparatus.

7. The method of claim 1, wherein a mean temperature of the inhomogeneous temperature distribution of the portion of the surface of the optical deviates by no more than ±0.5 K from a zero-crossing temperature of the optical element.

8. The method of claim 7, wherein the inhomogeneous temperature distribution reduces aberrations in the form of wavefront aberrations created on the portion of the surface of the optical element when the optical element is heated to the mean temperature during the break in operation of the microlithography projection exposure apparatus.

9. The method of claim 1, further comprising determining an inhomogeneous temperature distribution on the surface of the optical element which reduces the aberrations of the projection exposure apparatus.

10. The method of claim 9, wherein determining the inhomogeneous temperature distribution on the surface of the optical element comprises taking into account individual material-specific properties of the optical element.

11. The method of claim 1, wherein a heating power of the heating radiation to create the inhomogeneous temperature distribution used during the break in operation of the microlithography projection exposure apparatus is maintained during a subsequent exposure operation of the microlithography projection exposure apparatus in which the surface of the optical element is exposed to exposure radiation.

12. The method of claim 1, wherein a heating power of the heating radiation to create the inhomogeneous temperature distribution used during the break in operation of the microlithography projection exposure apparatus is modified during a subsequent exposure operation of the microlithography projection exposure apparatus in which the surface of the optical element is exposed to exposure radiation, thereby maintaining the inhomogeneous temperature distribution on the portion of the surface of the optical element during the exposure operation.

13. The method of claim 1, wherein the beam shaping element comprises a diffractive optical element.

14. The method of claim 1, wherein the beam shaping element comprises a portion of a diffractive optical element.

15. One or more machine-readable hardware storage devices comprising instructions that are executable by one or more processing devices to perform operations comprising the method of claim 1.

16. A system comprising:
one or more processing devices; and
one or more machine-readable hardware storage devices comprising instructions that are executable by the one or more processing devices to perform operations comprising the method of claim 1.

17. A microlithography projection exposure apparatus, comprising:
an optical element comprising a surface;
a heating device configured to, during a break in operation of the microlithography projection exposure apparatus when the surface of the optical element is not irradiated by exposure radiation, irradiate the surface of the optical element with heating radiation to create an inhomogeneous temperature distribution on a portion of the surface of the optical element to reduce aberrations of the microlithography projection exposure apparatus,
wherein the heating device comprises:
a heating radiation source configured to create heating radiation; and
a beam shaping element configured to create a continuous heating radiation profile.

18. The microlithography projection exposure apparatus of claim 17, wherein the microlithography projection exposure apparatus is configured so that the inhomogeneous temperature distribution on the portion of the surface of the optical element reduces aberrations of the microlithography projection exposure apparatus compared with a homogeneous temperature distribution on the portion of the surface of the optical element.

19. The microlithography projection exposure apparatus of claim 17, wherein the heating device is configured to create a mean temperature of the inhomogeneous temperature distribution on the portion of the surface of the optical element which deviates by no more than ±1.5 K from a zero-crossing temperature of the optical element.

20. The microlithography projection exposure apparatus of claim 17, wherein the heating device is designed configured so that, after the break in operation of the microlithography projection exposure apparatus and during an exposure operation of the microlithography projection exposure apparatus in which the portion of the surface of the optical element is exposed to exposure radiation, the heating device:
i) maintains a heating power of the heating radiation used to create the inhomogeneous temperature distribution during the break in operation of the microlithography projection exposure apparatus; or
ii) modifies the heating power of the heating radiation used to create the inhomogeneous temperature distribution during the break in operation of the microlithography projection exposure apparatus to maintain the inhomogeneous temperature distribution on the portion of the surface of the optical element during the exposure operation of the microlithography projection exposure apparatus.
